(19) United States
(12) Patent Application Publication
(10) Pub. No.: US 2025/0351496 A1
(43) Pub. Date: Nov. 13, 2025

(54) COMPOSITE SUBSTRATE AND MANUFACTURING METHOD FOR THE SAME

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/816,323

(22) Filed: Aug. 27, 2024

(30) Foreign Application Priority Data
May 10, 2024 (CN) 202410578417.X

(51) Int. Cl. H01L 29/32; C30B 29/40; C30B 33/10; H01L 21/306; H01L 21/308; H01L 27/12; H01L 29/04; H01L 29/20

(52) U.S. Cl. CPC H10D 62/53; C30B 29/403; C30B 29/406; C30B 33/10; H01L 21/30604; H01L 21/308; H10D 62/405; H10D 62/8503; H10D 86/201

(57) ABSTRACT

A manufacturing method includes: growing a group III nitride layer on a supporting substrate; bonding the group III nitride layer to a target substrate having a dielectric layer on a surface of the target substrate; removing the supporting substrate; and forming a plurality of hexagonal nanopores arranged at intervals on a side, away from the target substrate, of the group III nitride layer. The technical solutions of the present disclosure may reduce a stress caused by lattice mismatch and thermal mismatch between the group III nitride layer and a substrate, thereby improving a quality of a group III nitride substrate.

### CROSS-REFERENCE TO RELATED APPLICATIONS

The present application claims priority to Chinese Patent Application No. 202410578417.X, filed on May 10, 2024, which is hereby incorporated by reference in its entirety.

### TECHNICAL FIELD

The present disclosure relates to the field of semiconductor technologies, and in particular, to a composite substrate and a manufacturing method for the composite substrate.

### BACKGROUND

Group III nitride wide band gap materials are particularly suitable for high frequency, high power and other devices due to their excellent performance. Especially in the field of semiconductor devices, the group III nitride wide band gap materials have made remarkable achievements and considerable development in research on optoelectronic devices such as Light Emitting Diodes (LEDs) and Laser Diodes (LDs), and in research on microelectronic devices such as High Electron Mobility Transistors (HEMTs).

A material of substrate used for epitaxially growth of a group III nitride device should be the same material as the device as much as possible, so as to make a lattice mismatch of the device and the substrate small and a coefficient of thermal expansion low. However, since a group III nitride material has an extremely high melting point and a large nitrogen saturation vapor pressure, it is difficult to obtain a homogeneous substrate with a large area and a high quality.

### SUMMARY

In view of this, embodiments of the present disclosure provide a composite substrate and a manufacturing method for the same to solve a problem that a group III nitride substrate with a large area and a high quality is difficult to obtain.

According to one aspect of the present disclosure, an embodiment of the present disclosure provides a manufacturing method for a composite substrate, which includes: growing a group III nitride layer on a supporting substrate; bonding the group III nitride layer to a target substrate having a dielectric layer on a surface of the target substrate; removing the supporting substrate; and forming a plurality of hexagonal nanopores arranged at intervals on a side, away from the target substrate, of the group III nitride layer.

As an optional embodiment, the side, away from the target substrate, of the group III nitride layer is an N-face.

As an optional embodiment, a projection shape of each hexagonal nanopore in the plurality of hexagonal nanopores, on a plane where the target substrate is located, is an equilateral and equiangular hexagon, an equilateral but not equiangular hexagon, or an equiangular but not equilateral hexagon.

As an optional embodiment, a diameter of each hexagonal nanopore in the plurality of hexagonal nanopores ranges from 100 nm to 300 nm.

As an optional embodiment, a thickness of the group III nitride layer ranges from 0.5 times a diameter of each hexagonal nanopore in the plurality of hexagonal nanopores to 2 times the diameter of the hexagonal nanopore.

As an optional embodiment, the forming a plurality of hexagonal nanopores arranged at intervals on a side, away from the target substrate, of the group III nitride layer includes: depositing a mask layer on the side, away from the target substrate, of the group III nitride layer; photoetching the mask layer to form a plurality of through holes arranged at intervals; and performing wet processing on a surface of the group III nitride layer exposed by the plurality of through holes to form the plurality of hexagonal nanopores on the side, away from the target substrate, of the group III nitride layer.

As an optional embodiment, after the performing wet processing on a surface of the group III nitride layer exposed by the plurality of through holes to form the plurality of hexagonal nanopores on the side, away from the target substrate, of the group III nitride layer, the manufacturing method for the composite substrate further includes: performing secondary etching on the plurality of hexagonal nanopores, where an etching method for the secondary etching is in-situ etching.

As an optional embodiment, after the performing wet processing on a surface of the group III nitride layer exposed by the plurality of through holes to form the plurality of hexagonal nanopores on the side, away from the target substrate, of the group III nitride layer, the manufacturing method for the composite substrate further includes: performing secondary epitaxy in each hexagonal nanopore in the plurality of hexagonal nanopores to reduce a pore size of the hexagonal nanopore.

As an optional embodiment, the performing secondary epitaxy in each hexagonal nanopore in the plurality of hexagonal nanopores to reduce a pore size of the hexagonal nanopore includes: reducing the pore size of the hexagonal nanopore to less than 100 nm.

As an optional embodiment, after the performing secondary epitaxy in each hexagonal nanopore in the plurality of hexagonal nanopores, the manufacturing method for the composite substrate further includes: forming a modification layer on a sidewall of the hexagonal nanopore.

According to another aspect of the present disclosure, an embodiment of the present disclosure provides a composite substrate, which is prepared by any one of embodiments of the manufacturing method for the composite substrate. The composite substrate includes: a target substrate, a dielectric layer and a group III nitride layer which are sequentially stacked, where a side, away from the target substrate, of the group III nitride layer includes a plurality of hexagonal nanopores arranged at intervals.

As an optional embodiment, the side, away from the target substrate, of the group III nitride layer is an N-face.

As an optional embodiment, a projection shape of each hexagonal nanopore in the plurality of hexagonal nanopores, on a plane where the target substrate is located, is an equilateral and equiangular hexagon, an equilateral but not equiangular hexagon, or an equiangular but not equilateral hexagon.

As an optional embodiment, a crystal plane of a side surface of each hexagonal nanopore in the plurality of hexagonal nanopores includes a (1101) crystal plane.

As an optional embodiment, a bottom surface of each hexagonal nanopore in the plurality of hexagonal nanopores is located in the group III nitride layer, in an interface between the group III nitride layer and the dielectric layer, or in the dielectric layer.

### BRIEF DESCRIPTION OF THE DRAWINGS

FIG. 1 is a flowchart of a manufacturing method for a composite substrate according to an embodiment of the present disclosure.

FIG. 2 to FIG. 6 are schematic structural diagrams of intermediate structures corresponding to the flowchart shown in FIG. 1.

FIG. 7a to FIG. 7c are top views of composite substrates according to some embodiments of the present disclosure.

FIG. 8a to FIG. 8c are schematic structural diagrams of composite substrates according to some embodiments of the present disclosure.

FIG. 9 is a flowchart of a method for forming hexagonal nanopores of a composite substrate according to an embodiment of the present disclosure.

FIG. 10 to FIG. 12 are schematic structural diagrams of intermediate structures corresponding to the flowchart shown in FIG. 9.

FIG. 13 is a schematic structural diagram of a composite substrate according to an embodiment of the present disclosure.

### DETAILED DESCRIPTION OF THE EMBODIMENTS

Technical solutions in embodiments of the present disclosure are described clearly and completely below with reference to the drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

In order to solve the problem that a group III nitride substrate with a large area and a high quality is difficult to obtain, the present disclosure provides a composite substrate and a manufacturing method for the same. The manufacturing method may include: growing a group III nitride layer on a supporting substrate; bonding the group III nitride layer to a target substrate having a dielectric layer on a surface of the target substrate; removing the supporting substrate; and forming a plurality of hexagonal nanopores arranged at intervals on a side, away from the target substrate, of the group III nitride layer. The present disclosure may reduce a stress caused by lattice mismatch and thermal mismatch between the group III nitride layer and a substrate through a method of inverted bonding and stripping the substrate, improving a quality of the group III nitride layer (that is a group III nitride substrate), and at the same time, the group III nitride layer on an insulator may be obtained, thereby reducing a parasitic capacitance between the group III nitride layer and the substrate. An epitaxial growth surface of the composite substrate prepared by the present disclosure is a group III nitride layer, and it is homoepitaxial when a group III nitride device is epitaxially grown on the composite substrate. Therefore, the composite substrate prepared by the present disclosure is equivalent to a homogeneous substrate of a group III nitride device, which may be configured to prepare a group III nitride GaN-based device with few defects and a high quality. Meanwhile, in the present disclosure, hexagonal nanopores are disposed on an easily etched N-face of the group III nitride layer, and on one hand, a stress caused by lattice mismatch and thermal mismatch of each epitaxial layer above the composite substrate may be alleviated, on the other hand, the epitaxial layer above the composite substrate may heal defects through lateral epitaxial growth, thus further improving a quality of a GaN-based device laterally epitaxially grown above the group III nitride and prepared on the composite substrate.

A composite substrate and a manufacturing method for the same mentioned in the present disclosure are further illustrated with examples below with reference to FIG. 1 to FIG. 13.

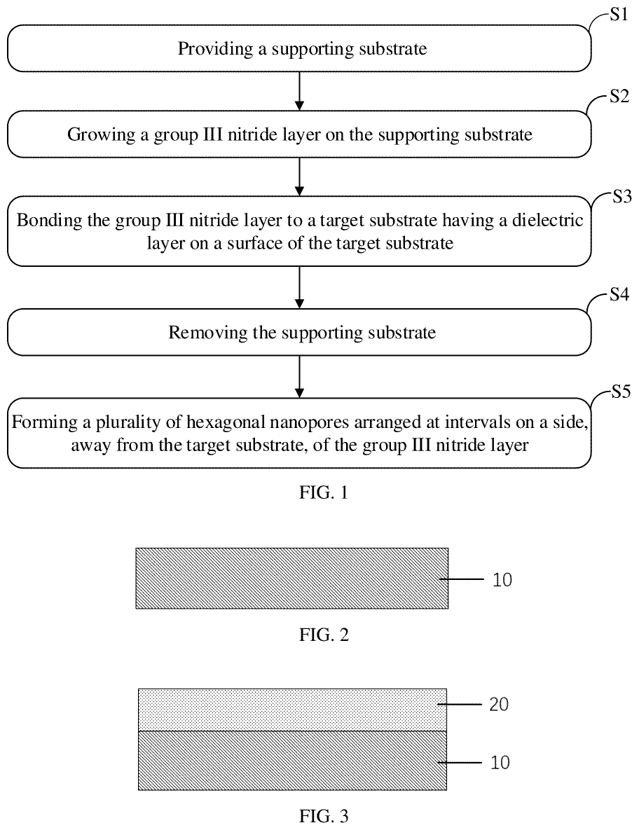

FIG. 1 is a flowchart of a manufacturing method for a composite substrate according to an embodiment of the present disclosure; and FIG. 2 to FIG. 6 are schematic structural diagrams of intermediate structures corresponding to the flowchart shown in FIG. 1. As shown in FIG. 1, a manufacturing method for a composite substrate provided by an embodiment of the present disclosure may include the following steps.

S1: providing a supporting substrate.

Specifically, as shown in FIG. 2, a supporting substrate 10 is provided, and a material of the supporting substrate 10 includes silicon.

S2: growing a group III nitride layer on the supporting substrate.

Specifically, as shown in FIG. 3, a group III nitride layer 20 is grown on the supporting substrate 10, and a material of the group III nitride layer 20 includes at least one of GaN or AlN.

S3: bonding the group III nitride layer to a target substrate having a dielectric layer on a surface of the target substrate.

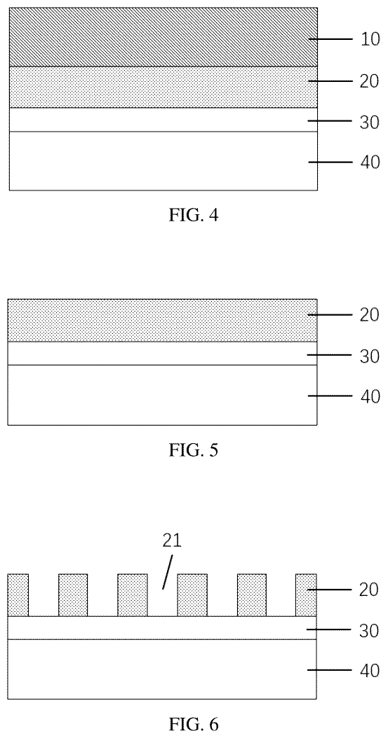

Specifically, as shown in FIG. 4, the group III nitride layer 20 is bonded to a target substrate 40 having a dielectric layer 30 on a surface of the target substrate 40. A material of the target substrate 40 includes silicon, and a material of the dielectric layer 30 includes at least one of silicon oxide, silicon nitride, silicon oxynitride and aluminum nitride.

S4: removing the supporting substrate.

Specifically, the supporting substrate 10 is removed to form a composite substrate as shown in FIG. 5. A method of inverted bonding and stripping the supporting substrate 10 may reduce a stress caused by lattice mismatch and thermal mismatch between a group III nitride material and a substrate material, improving a quality of the group III nitride layer 20. At the same time, the group III nitride layer 20 on an insulator may be obtained, thereby reducing a parasitic capacitance between the group III nitride layer 20 and the target substrate 40.

S5: forming a plurality of hexagonal nanopores arranged at intervals on a side, away from the target substrate, of the group III nitride layer.

Specifically, a plurality of hexagonal nanopores 21 arranged at intervals are formed on a side, away from the target substrate 40, of the group III nitride layer 20, to form a composite substrate as shown in FIG. 6. After the group III nitride layer 20 is flip-bonded to the dielectric layer 30 and the supporting substrate 10 is stripped, the side, away from the target substrate 40, of the group III nitride layer 20 is an N-face, and the N-face of the group III nitride material is easier to be etched, thereby reducing a etching difficulty.

In this embodiment, a crystal plane of a side surface of the hexagonal nanopore 21 includes a (1101) crystal plane. A diameter of the hexagonal nanopore 21 ranges from 100 nm to 300 nm. A thickness of the group III nitride layer 20 is comparable to a diameter of the hexagonal nanopore 21, and the thickness of the group III nitride layer 20 ranges from 0.5 times the diameter of the hexagonal nanopore 21 to 2 times the diameter of the hexagonal nanopores 21.

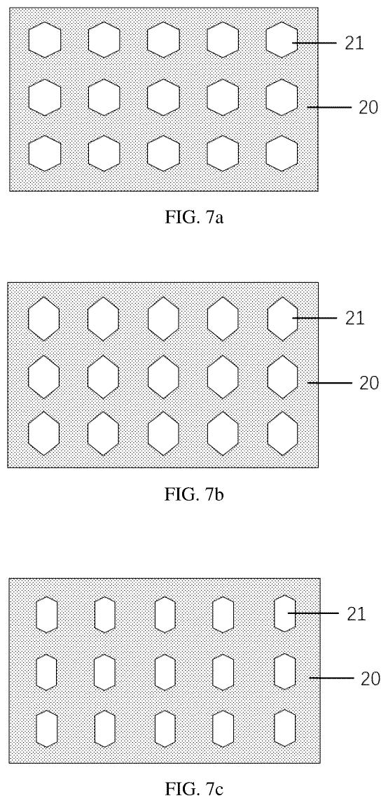

In an embodiment, FIG. 7a to FIG. 7c are top views of composite substrates according to some embodiments of the present disclosure. A projection shape of the hexagonal nanopore 21, on a plane where the target substrate 40 is located, is an equilateral and equiangular hexagon (as shown in FIG. 7a), an equilateral but not equiangular hexagon (as shown in FIG. 7b), or an equiangular but not equilateral hexagon (as shown in FIG. 7c). Optionally, hexagonal nanopores 21 may be uniformly distributed, that is, a spacing between adjacent hexagonal nanopores is not changed. Or, hexagonal nanopores 21 may be unevenly distributed, that is, the spacing between adjacent hexagonal nanopores changes, for example, periodically changing, uniformly increasing from a center to the periphery, or uniformly decreasing from the center to the periphery. By changing a shape and distribution of hexagonal nanopores 21, an overall stress distribution of a device subsequently prepared on the composite substrate may be adjusted, thereby improving the reliability of the device.

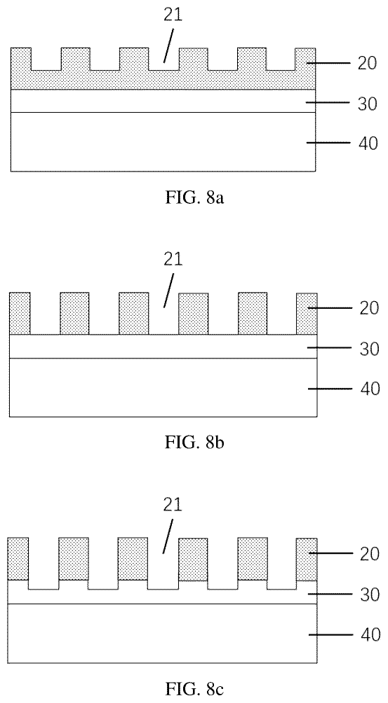

In an embodiment, FIG. 8a to FIG. 8c are schematic structural diagrams of composite substrates according to some embodiments of the present disclosure. A bottom surface of the hexagonal nanopore 21 is located in the group III nitride layer 20 (as shown in FIG. 8a), in an interface between the group III nitride layer 20 and the dielectric layer 30 (as shown in FIG. 8b), or in the dielectric layer 30 (as shown in FIG. 8c). A material of the dielectric layer 30 is different from a material of an easily etched group III nitride layer 20, and has an etching selectivity ratio. Therefore, the dielectric layer 30 may be used as an etching stop layer when etching the hexagonal nanopore 21 in the group III nitride layer 20 to control an etching depth of the hexagonal nanopore 21.

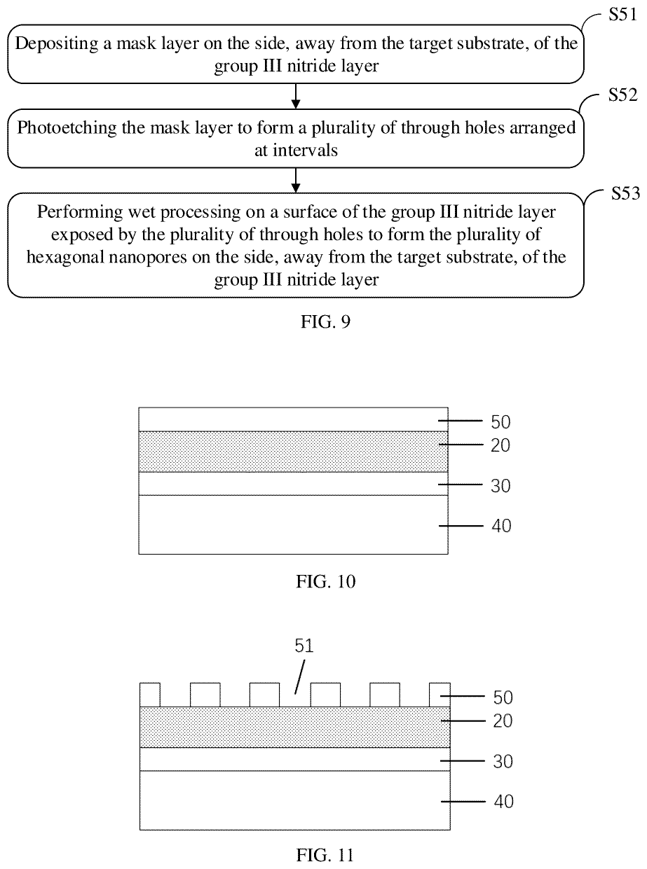

In an embodiment, FIG. 9 is a flowchart of a method for forming hexagonal nanopores of a composite substrate according to an embodiment of the present disclosure; and FIG. 10 to FIG. 12 are schematic structural diagrams of intermediate structures corresponding to the flowchart shown in FIG. 9. As shown in FIG. 9, the method for forming hexagonal nanopores of the composite substrate provided by an embodiment of the present disclosure, that is the step S5, includes the following steps.

S51: depositing a mask layer on the side, away from the target substrate, of the group III nitride layer.

S52: photoetching the mask layer to form a plurality of through holes arranged at intervals.

S53: performing wet processing on a surface of the group III nitride layer exposed by the plurality of through holes to form the plurality of hexagonal nanopores on the side, away from the target substrate, of the group III nitride layer.

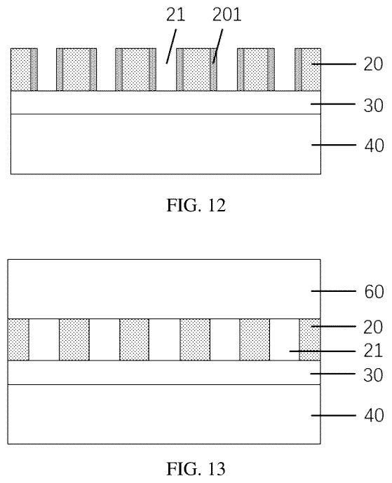

Specifically, as shown in FIG. 10, a mask layer 50 is deposited on the side, away from the target substrate 40, of the group III nitride layer 20, as shown in FIG. 11, the mask layer 50 is photoetched to form the plurality of through holes arranged at intervals, and then wet processing is performed on a surface of the group III nitride layer 20 exposed by the through holes 51, to form the plurality of hexagonal nanopores 21 arranged at intervals on the side, away from the target substrate 40, of the group III nitride layer 20, and to form the composite substrate as shown in FIG. 6. Optionally, after forming the plurality of hexagonal nanopores arranged at intervals on the side, away from the target substrate, of the group III nitride layer, secondary etching is performed on the hexagonal nanopores 21. This etching method is in-situ etching, which may further modify the hexagonal nanopore 21, so as to improve a crystal quality of a sidewall and the bottom surface of the hexagonal nanopore 21. Optionally, secondary epitaxy is performed in the hexagonal nanopore 21 to reduce a pore size of the hexagonal nanopore 21 to less than 100 nm. As shown in FIG. 12, after performing secondary epitaxy in the hexagonal nanopore 21, a modification layer 201 may be formed on a sidewall of the hexagonal nanopore 21, which may also further modify the hexagonal nanopore 21 to improve the crystal quality of the sidewall and the bottom surface of the hexagonal nanopore 21.

According to another aspect of the present disclosure, the present disclosure provides a composite substrate, which is prepared by the above manufacturing method for a composite substrate. As shown in FIG. 6, the composite substrate may include a target substrate 40, a dielectric layer 30, and a group III nitride layer 20 which are sequentially stacked, where a side, away from the target substrate 40, of the group III nitride layer 20 includes a plurality of hexagonal nanopores 21 arranged at intervals. In this embodiment, a material of the target substrate 40 includes silicon, a material of the dielectric layer 30 includes at least one of silicon oxide, silicon nitride, silicon oxynitride and aluminum nitride, and a material of the group III nitride layer 20 includes at least one of GaN or AlN. The side, away from the target substrate 40, of the group III nitride layer 20 is an N-face, a crystal plane of a side surface of the hexagonal nanopore 21 includes a (1101) crystal plane, and a thickness of the group III nitride layer 20 ranges from 0.5 times a diameter of the hexagonal nanopore 21 to 2 times the diameter of the hexagonal nanopore 21.

In an embodiment, a projection shape of the hexagonal nanopore 21, on a plane where the target substrate 40 is located, is an equilateral and equiangular hexagon (as shown in FIG. 7a), an equilateral but not equiangular hexagon (as shown in FIG. 7b), or an equiangular but not equilateral hexagon (as shown in FIG. 7c). By changing a shape of the hexagonal nanopore 21, an overall stress distribution of a device subsequently prepared on the composite substrate may be adjusted, thereby improving the reliability of the device.

In an embodiment, a bottom surface of the hexagonal nanopore 21 is located in the group III nitride layer 20 (as shown in FIG. 8a), in an interface between the group III nitride layer 20 and the dielectric layer 30 (as shown in FIG. 8b), or in the dielectric layer 30 (as shown in FIG. 8c). The dielectric layer 30 may be used as an etching stop layer to control an etching depth of the hexagonal nanopore 21.

In an embodiment, FIG. 13 is a schematic structural diagram of a composite substrate according to an embodiment of the present disclosure. As shown in FIG. 13, a device layer 60 is further included above the group III nitride layer 20, and a material of the device layer 60 includes a group III nitride material. The device layer 60 is grown on the group III nitride layer 20 through lateral epitaxial growth, which may heal defects, the device layer 60 and the group III nitride layer 20 have less mismatch, and therefore, the device layer 60 with a good crystal quality may be grown on the group III nitride layer 20.

The present disclosure provides a composite substrate and a manufacturing method for the same. In the embodiments of the present disclosure, a group III nitride layer is grown on a supporting substrate, the group III nitride layer is bonded to a target substrate having a dielectric layer on a surface of the target substrate, the supporting substrate is removed and a plurality of hexagonal nanopores arranged at intervals are formed on a side, away from the target substrate, of the group III nitride layer. The present disclosure may reduce a stress caused by lattice mismatch and thermal mismatch between the group III nitride layer and a substrate through a method of inverted bonding and stripping the substrate, improving the quality of the group III nitride layer, and at the same time, the group III nitride layer on an insulator may be obtained, thereby reducing a parasitic capacitance between the group III nitride layer and the substrate. An epitaxial growth surface of the composite substrate prepared by the present disclosure is a group III nitride layer, and it is homoepitaxial when a group III nitride device is epitaxially grown on the composite substrate. Therefore, the composite substrate prepared by the present disclosure is equivalent to a homogeneous substrate of a group III nitride device, which may be configured to prepare a group III nitride device with few defects and a high quality. Meanwhile, in the present disclosure, hexagonal nanopores are disposed on an easily etched N-face of the group III nitride layer, and on one hand, a stress caused by lattice mismatch and thermal mismatch of each epitaxial layer above the composite substrate may be alleviated, on the other hand, the epitaxial layer above the composite substrate may heal defects through lateral epitaxial growth, thus further improving a quality of a group III nitride device prepared on the composite substrate.

It should be understood that the terms “including” and its modification used in this disclosure are open-ended, that is, “including but not limited to”. The term “an embodiment” represents “at least one embodiment”; and the term “another embodiment” means “at least one another embodiment”. In this specification, a schematic description of foregoing terms does not have to be directed to a same embodiment or example. Further, specific features, structures, materials, or characteristics described may be incorporated in an appropriate manner in any one or more embodiments or examples. In addition, without being contradictory, a person skilled in the art may combine and permutate different embodiments or examples described in this specification and features of different embodiments or examples.

The foregoing descriptions are merely exemplary embodiments of the present disclosure, and are not intended to limit the present disclosure. Any modification, an equivalent replacement, or the like made within a spirit and principles of the present disclosure shall be included in a protection scope of the present disclosure.

What is claimed is:

1. A manufacturing method for a composite substrate, comprising:
growing a group III nitride layer on a supporting substrate;
bonding the group III nitride layer to a target substrate having a dielectric layer on a surface of the target substrate;
removing the supporting substrate; and
forming a plurality of hexagonal nanopores arranged at intervals on a side, away from the target substrate, of the group III nitride layer.

2. The manufacturing method for the composite substrate according to claim 1, wherein the side, away from the target substrate, of the group III nitride layer is an N-face.

3. The manufacturing method for the composite substrate according to claim 1, wherein a projection shape of each hexagonal nanopore in the plurality of hexagonal nanopores, on a plane where the target substrate is located, is an equilateral and equiangular hexagon, an equilateral but not equiangular hexagon, or an equiangular but not equilateral hexagon.

4. The manufacturing method for the composite substrate according to claim 1, wherein a crystal plane of a side surface of each hexagonal nanopore in the plurality of hexagonal nanopores comprises a (1101) crystal plane.

5. The manufacturing method for the composite substrate according to claim 1, wherein a bottom surface of each hexagonal nanopore in the plurality of hexagonal nanopores is located in the group III nitride layer, in an interface between the group III nitride layer and the dielectric layer, or in the dielectric layer.

6. The manufacturing method for the composite substrate according to claim 1, wherein a diameter of each hexagonal nanopore in the plurality of hexagonal nanopores ranges from 100 nm to 300 nm.

7. The manufacturing method for the composite substrate according to claim 1, wherein a thickness of the group III nitride layer ranges from 0.5 times a diameter of each hexagonal nanopore in the plurality of hexagonal nanopores to 2 times the diameter of the hexagonal nanopore.

8. The manufacturing method for the composite substrate according to claim 1, wherein the forming a plurality of hexagonal nanopores arranged at intervals on a side, away from the target substrate, of the group III nitride layer comprises:
depositing a mask layer on the side, away from the target substrate, of the group III nitride layer;
photoetching the mask layer to form a plurality of through holes arranged at intervals; and
performing wet processing on a surface of the group III nitride layer exposed by the plurality of through holes to form the plurality of hexagonal nanopores on the side, away from the target substrate, of the group III nitride layer.

9. The manufacturing method for the composite substrate according to claim 8, wherein after the performing wet processing on a surface of the group III nitride layer exposed by the plurality of through holes to form the plurality of hexagonal nanopores on the side, away from the target substrate, of the group III nitride layer, the manufacturing method for the composite substrate further comprises:
performing secondary etching on the plurality of hexagonal nanopores, wherein an etching method for the secondary etching is in-situ etching.

10. The manufacturing method for the composite substrate according to claim 8, wherein after the performing wet processing on a surface of the group III nitride layer exposed by the plurality of through holes to form the plurality of hexagonal nanopores on the side, away from the target substrate, of the group III nitride layer, the manufacturing method for the composite substrate further comprises:
performing secondary epitaxy in each hexagonal nanopore in the plurality of hexagonal nanopores to reduce a pore size of the hexagonal nanopore.

11. The manufacturing method for the composite substrate according to claim 10, wherein the performing secondary epitaxy in each hexagonal nanopore in the plurality of hexagonal nanopores to reduce a pore size of the hexagonal nanopore comprises:
reducing the pore size of the hexagonal nanopore to less than 100 nm.

12. The manufacturing method for the composite substrate according to claim 10, wherein after the performing secondary epitaxy in each hexagonal nanopore in the plurality of hexagonal nanopores, the manufacturing method for the composite substrate further comprises:
forming a modification layer on a sidewall of the hexagonal nanopore.

13. A composite substrate, comprising: a target substrate, a dielectric layer and a group III nitride layer which are sequentially stacked, wherein a side, away from the target substrate, of the group III nitride layer comprises a plurality of hexagonal nanopores arranged at intervals.

14. The composite substrate according to claim 13, wherein a material of the group III nitride layer comprises at least one of GaN or AlN.

15. The composite substrate according to claim 13, wherein the side, away from the target substrate, of the group III nitride layer is an N-face.

16. The composite substrate according to claim 13, wherein a projection shape of each hexagonal nanopore in the plurality of hexagonal nanopores, on a plane where the target substrate is located, is an equilateral and equiangular hexagon, an equilateral but not equiangular hexagon, or an equiangular but not equilateral hexagon.

17. The composite substrate according to claim 13, wherein a crystal plane of a side surface of each hexagonal nanopore in the plurality of hexagonal nanopores comprises a (1101) crystal plane.

18. The composite substrate according to claim 13, wherein a bottom surface of each hexagonal nanopore in the plurality of hexagonal nanopores is located in the group III nitride layer, in an interface between the group III nitride layer and the dielectric layer, or in the dielectric layer.

19. The composite substrate according to claim 13, wherein a thickness of the group III nitride layer ranges from 0.5 times a diameter of each hexagonal nanopore in the plurality of hexagonal nanopores to 2 times the diameter of the hexagonal nanopore.

20. The composite substrate according to claim 13, wherein a material of the dielectric layer comprises at least one of silicon oxide, silicon nitride, silicon oxynitride and aluminum nitride.
